(19) United States
(12) Patent Application Publication
(10) Pub. No.: US 2009/0255576 A1
(43) Pub. Date: Oct. 15, 2009

(54) WINDOW SOLAR CELL

(76) Inventor: Michael Tischler, Phoenix, AZ (US)

Correspondence Address: FOLEY & LARDNER LLP, P.O. BOX 80278, SAN DIEGO, CA, 92138-0278, US

(21) Appl. No.: 12/417,574

(22) Filed: Apr. 2, 2009

Related U.S. Application Data
(60) Provisional application No. 61/042,494, filed on Apr. 4, 2008.

(51) Int. Cl. H01L 31/00

(52) U.S. Cl. 136/255; 136/256

(57) ABSTRACT

A substantially transparent solar cell is combined with an electrochromic film.

### CROSS-REFERENCE TO RELATED APPLICATION

This patent application claims priority to U.S. Provisional Patent Application No. 61/042,494, entitled “WINDOW SOLAR CELL,” filed Apr. 4, 2008, which is hereby incorporated by reference in its entirety for all purposes.

### BACKGROUND OF THE INVENTION

This application relates generally to solar cell systems. More specifically, this application relates to the production and use of transparent or translucent solar cells.

While there have long been concerns about the development of energy sources, some of these concerns have become particularly acute in the last several years. These concerns are largely twofold: there is a concern that the use of certain energy sources, particularly those that are carbon-based, have undesirable environmental impacts. These energy sources are also largely nonrenewable, presenting concerns about the systematic depletion of them. Many alternatives have been proposed for producing energy that are drawn from sources that have low environmental impacts and are renewable, but many of these proposals suffer from a variety of inefficiencies related to the generation techniques.

In addition, many of these proposals suffer from the fact that they require substantial modifications to existing infrastructures. While the energy generation from the techniques themselves may be attractive and generally efficient, the impact on infrastructure makes them uneconomical. In addition, there are numerous regulatory provisions that have the potential to frustrate attempts to deploy new energy-generation technologies. Navigating such a regulatory framework frequently acts to discourage large-scale implementation of many promising forms of technology.

One set of techniques for generating energy that has persistently been promising makes use of solar cells to collect light and generate energy from the collected light. It would generally be advantageous to place solar cells on the surfaces of a variety of structures, but the ability to deploy current solar cells is limited by the fact that they are generally opaque. For example, in applications where it might be desirable to place solar cells on buildings, they compete with space for windows. While there has been some work on transparent or translucent solar cells, a transparent or translucent solar cell may advantageously permit transmission of the same percentage of light as a window.

There is accordingly a general need in the art for improved methods and systems of producing solar cells.

### BRIEF SUMMARY OF THE INVENTION

Embodiments of the invention combine a substantially transparent solar cell with an electrochromic film. The solar cell may comprise a material having a band gap equal to or larger than the photon energies over some portion of the visible spectrum. The material may comprise a doped material and examples of the material include SiC, GaN, GaP, GaS, AlAs, AlP, CdS, ZnTe, ZnSe, ZnS, or an alloy thereof. The solar cell may be a single-junction solar cell, a multifunction solar cell, or a multiband solar cell in different embodiments. It may also have a thickness less than 10 μm.

Other embodiments of the invention comprise objects and devices comprising the combined solar cell and electrochromic film, such as a device powered by energy generated with the solar cell.

### BRIEF DESCRIPTION OF THE DRAWINGS

A further understanding of the nature and advantages of the present invention may be realized by reference to the remaining portions of the specification and the drawings wherein like reference numerals are used throughout the several drawings to refer to similar components.

FIG. 1 is a schematic illustration of the structure of a typical office building that highlights portions having different desired optical characteristics;

FIG. 2 provides a schematic illustration of a solar-cell structure that may be used in accordance with embodiments of the invention;

FIGS. 3A-3C illustrate the electronic structure of different types of monocrystalline solar cells; and

FIG. 4 is a flow diagram summarizing various aspects of methods of the invention.

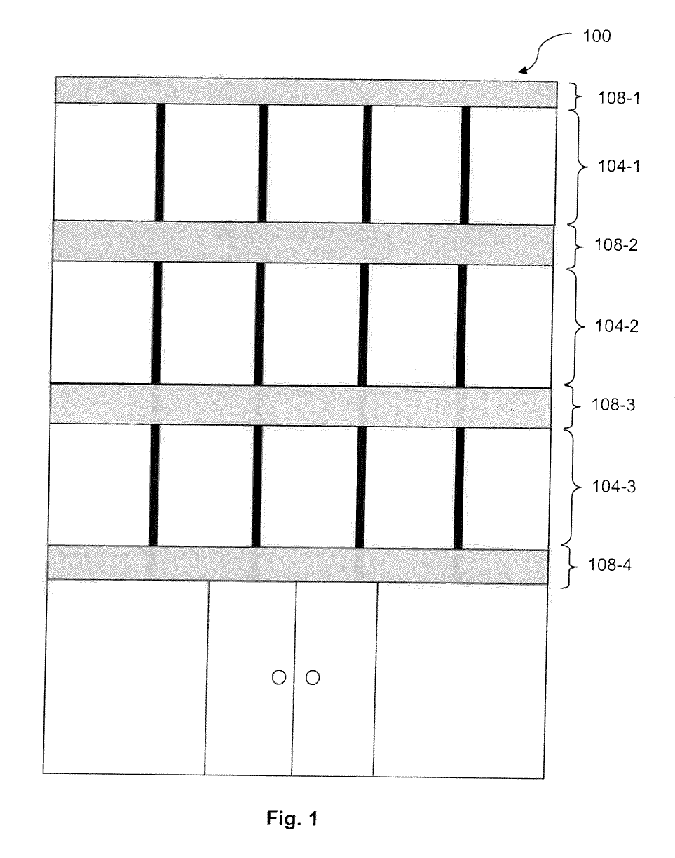

### DETAILED DESCRIPTION OF THE INVENTION

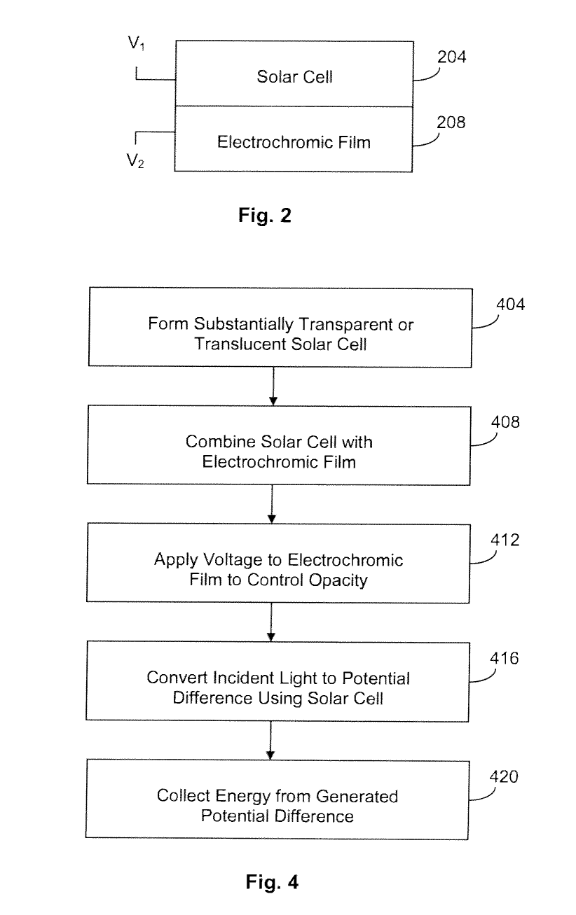

Embodiments of the invention provide solar cell structures that can take on substantially transparent or translucent states and can take on substantially opaque states. The basic structure is illustrated schematically in FIG. 2 and comprises a solar cell 204 and an electrochromic film 208. The solar cell 204 is substantially transparent or translucent and the electrochromic film 208 may be disposed on either side of the solar cell 204, i.e. on a side that receives light directly or on a side that receives light transmitted through the solar cell.

The solar cell 204 itself is made of a material that is transparent or translucent in the visible wavelength range of light from about 400 nm to about 700 nm. Such a solar cell may transmit a portion of the incident energy that is detectable by the human visual system. In some embodiments, the solar cell may pass some portion of the energy over the entire range of the visible spectrum, while in other embodiments it may completely block some frequencies while passing other frequencies, or include combinations of these scenarios. Examples of semiconductors that appear substantially transparent or translucent, depending on the presence and level of different dopants, include SiC, GaN, GaP, GaS, AlAs, AlP, CdS, ZnTe, ZnSe, ZnS, and alloys of these materials. For example, high-purity SiC is clear, while n-type SiC has a green color and p-type SiC has a blue color. In some embodiments, the solar cell may comprise any of these semiconductors, undoped or doped, for example with about 0.01% to about 10% N.

In a specific example, GaP substrates with moderate n-type doping are substantially clear with a yellow tint. In accordance with an embodiment of the invention, a solar cell made from a dilute nitride system containing such elements as Ga, In, As, P, and N is used to for a multiband solar cell. It may be formed in a several-micron-thick layer. The substrate may be removed in such an embodiment, resulting in a substantially transparent solar cell. Such a solar cell may capture a large portion of the solar spectrum with a thickness relatively small compared with multijunction solar cells.

In another example, such elements as Ga In, As, and P may be used to form a single-junction solar cell on a GaP substrate as described above. Alternatively, other transparent substrates, such as SiC or sapphire, may be used. The substrate may be located between the solar cell material and the electrochromic film. In this case, the solar-cell efficiency may be reduced from the example above, but provide increased transparency.

In a further example, the solar cell material is selected to absorb mainly in the ultraviolet portion of the electromagnetic spectrum, outside of the visible spectrum. This results in a substantially transparent solar cell that may absorb the ultraviolet portion of the solar radiation, but pass visible radiation. For example, a solar cell structure of an embodiment of the present invention may absorb in the UV electromagnetic spectrum; that is, the solar cell may be substantially absorbing at wavelengths less than about 400 nm, but substantially transparent at wavelengths greater than 500 nm.

The level of transparency also depends on the thickness of the solar cell 204. Even if a bulk material is opaque, it can be rendered transparent if it is sufficiently thin. One example of this is silicon, which permits light transmission in a portion of the visible spectrum when its thickness is no more than several microns.

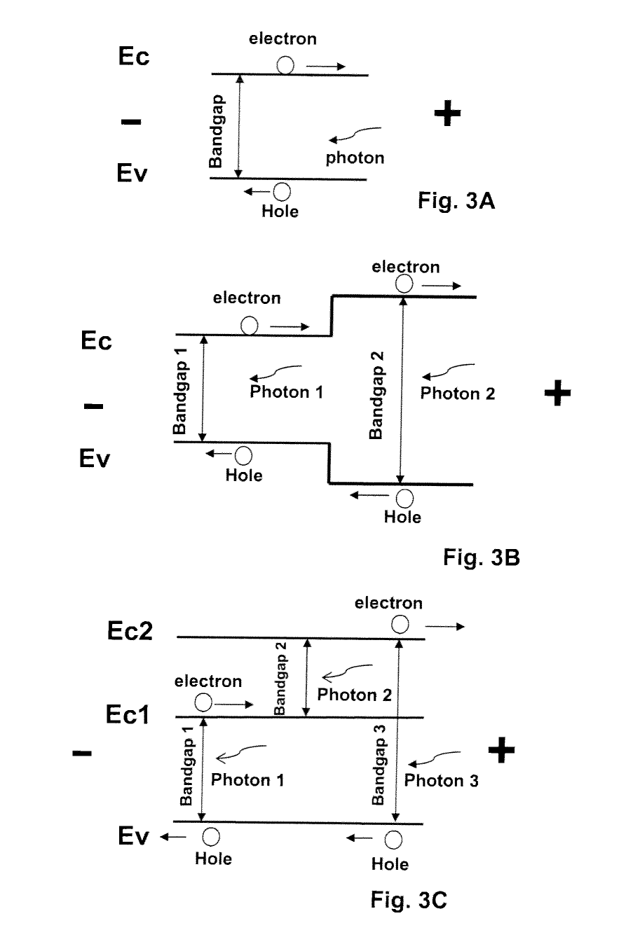

Embodiments of the invention use either singly or in combination a very thin solar cell and/or a solar cell made of materials with bandgaps that permit transmission of all or a portion of the visible spectrum. There are a variety of different electronic structures that may be used for the solar cell, as illustrated schematically with FIGS. 3A-3C. The simplest structure, illustrated in FIG. 3A, makes use of a single junction. Specifically, a single bandgap material is used to capture a portion of the solar spectrum, with photons that have an energy greater than the bandgap of the material being absorbed to create an electron-hole pair that produces a DC current under the action of an electric field. The conversion efficiency for a single-junction cell has a peak at the bandgap of the active region and decreases rapidly for higher energies. Using a single bandgap to convert a substantial portion of the solar spectrum is therefore relatively inefficient, with a theoretical maximum efficiency of 35% but with typical efficiencies actually using this technology being on the order of 15-20%.

Conversion of the available solar spectrum to electrical energy may be improved by using multiple junctions. This can be accomplished by engineering multiple bandgaps into a single cell. This is illustrated schematically with FIG. 3B, in which individual cells with different bandgaps are grown monolithically on top of one another with the largest bandgap material located at the top of the stack. With this approach, a larger portion of the incident energy is able to be absorbed, thereby increasing the total efficiency of the cell. The most popular approach to multijunction cells currently being researched are based on lattice-matched GaInP/GaAs double-junction cells and GaInP/GaAs/Ge triple junction cells and achieve maximum efficiencies on the order of 30-35% in practice. The theoretical maximum efficiency for the use of two-junction cells is 50% and the theoretical maximum efficiency for the use of three-junction cells is 56%.

A more sophisticated approach that has been explored at least theoretically is a multiple-band technique in which the number of bandgaps within a single cell is increased without the use of multiple materials. Introduction of a small fraction of highly electronegative atoms into a host semiconductor material has been shown to dramatically alter the electronic band structure of the host material by splitting the conduction band into two sub-bands. Because of the interaction between the two subbands, one subband is pushed to an energy higher than that of the bandgap of the host semiconductor and the other subband is pushed to a lower energy. This results in the creation of an additional energy level in the base structure to provide for three optical transitions as shown in FIG. 3C. The structure is therefore functionally equivalent to a triple-junction cell. The theoretical maximum efficiency using this approach is approximately 63%. The inclusion of still additional bands using this technique promises even higher efficiencies, with four-band approaches providing a theoretical maximum efficiency of 72%.

Irrespective of the specific electronic structure used for the solar cell 104, it is designed to capture and convert a portion of the visible spectrum of light to electricity, while transmitting enough light in the visible spectrum to provide sufficient transparency for particular applications. The design of such solar cells is a tradeoff between capturing and converting light to make power and achieve high efficiency and transmitting light to provide high transparency. This tradeoff may advantageously be effected at a different design point for different applications.

Returning to FIG. 2, the electrochromic film 208 may have states that are substantially transparent or substantially opaque depending on the application of a potential difference applied to the film indicated by voltage V₂. In some embodiments, certain voltages may render the electrochromic film 208 partially opaque, allowing the structure as a whole to appear tinted. Voltage V₁ represents the potential difference resulting in the solar cell 204 as light is converted into electrical energy.

The structure shown in FIG. 2 may be applied to window or windowlike structures so that light incident on the window may be used in generating power with the solar cell. Because the solar cell is substantially transparent, the window structure is substantially clear when the electrochromic film is in a transparent state. When the electrochromic film is substantially opaque, light may still reach the solar cell if the solar cell is on the side where light is incident on the window, allowing the structure to continue to generate power even when light does not pass through the window.

In some embodiments, one or more of the solar cells comprises a dilute nitride absorbing layer and an emitter layer. The dilute nitride absorbing layer may be provided as a ternary, quaternary, quinary, or higher alloy. But in addition to including at least one group-III element and at least one group-V element, the absorbing layer in these embodiments includes nitrogen. Examples of group-III elements that may be used comprise Ga, In, and Al, among others, and examples of group-V elements that may be used comprise As, P, Sb, and S, among others. An exemplary range for a concentration of the nitrogen in the absorbing layer is about 0.01-10.0 at. %, such as about 0.01-5.0 at. %. Thus, the absorbing layer comprises a material with the general formula GaₓIn_{y}Al_{z}NₐAs_{b}P_{c}Sb_{d}Sₑ, where x<1, y<1, z<1, 0.0001<a<0.1, b<1, c<1, d<1 and e<1.

The electrically active carrier concentration in illustrative embodiments is between 10¹⁶ and 5×10¹⁸ cm⁻³. The absorbing layer functions by absorbing photons to create electron-hole pairs. Further discussion of this absorption mechanism is described in greater detail below. A suitable thickness for the absorbing layer in different embodiments is within the range of about 1.0-10.0 μm.

The emitter may be doped using carriers of the opposite charge to those used in the absorbing layer. For example, in those embodiments where the absorbing layer is n-type doped, the emitter may be p-type doped. In one such group of examples, the emitter has an electrically active carrier concentration in the range 10¹⁷-10²⁰ cm⁻³. The emitter layer may advantageously have a larger bandgap than the absorbing layer, thereby minimizing surface recombination as described further below. Examples of materials that may be used for a p-type emitter layer include GaP, AlAs, AlInP, AlPAs. AlInAsP, InGaP, and ZnSe, among others. A suitable thickness of the emitter layer is between about 0.05 and 1.0 μm.

There are a number of other general considerations relevant to specific compositions in the solar-cell structure. For example, consider the case where the dilute nitride absorbing layer comprises GaNₓAs_{y}P_{1-x-y}, with x between 0.1 and 10.0 at %, and. For such a material system to exhibit multiband properties, x and y should be selected so that there is sufficient incorporation of active nitrogen to separate the conduction band from the intermediate band. This may be achieved in embodiments of the invention with x>0.01. At the same time, the phosphorus concentration may be selected to provide a direct F bandgap that is less than the indirect X bandgap. This is achieved in specific embodiments with 0.35<(1-x-y)<0.50. In particular embodiments, 0.005≦x≦0.050 and 0.3≦y≦0.7. Additionally, the compositions within this range may be selected to achieve relatively higher carrier mobility in the Ec2 conduction band, and minimize the conduction-band discontinuities, enhancing transport through the device.

A general overview of methods of the invention is accordingly provided with the flow diagram of FIG. 4. Although the drawing identifies specific steps to be performed and illustrates them in an exemplary order, this is not intended to be limiting. More generally, the methods of the invention may include additional steps, omit some of the indicated steps, and/or perform the steps in an order different from what is indicated.

The illustrated embodiment begins at block 404 by forming a substantially transparent or translucent solar cell. This is combined with an electrochromic film at block 408 so that a voltage may be applied to the electrochromic film at block 412 to control its opacity. Incident light is converted to a potential difference using the solar cell at block 416, allowing energy to be collected from the generated potential difference at block 420.

Thus, having described several embodiments, it will be recognized by those of skill in the art that various modifications, alternative constructions, and equivalents may be used without departing from the spirit of the invention. Accordingly, the above description should not be taken as limiting the scope of the invention, which is defined in the following claims.

What is claimed is:

1. A solar cell structure comprising:
an electrochromic film; and
a substantially transparent solar cell disposed over the electrochromic film.

2. The solar cell structure recited in claim 1 wherein the substantially transparent solar cell comprises a material having a band gap equal to or larger than photon energies of light from a visible portion of a solar spectrum.

3. The solar cell structure recited in claim 2 wherein the material comprises SiC, GaN, GaP, GaS, AlAs, AlP, CdS, ZnTe, ZnSc, ZnS, or an alloy thereof.

4. The solar cell structure recited in claim 3 wherein the material further comprises in a range of about 0.01% to about 10%.

5. The solar cell structure recited in claim 1 wherein the solar cell is a single-junction solar cell.

6. The solar cell structure recited in claim 1 wherein the solar cell is a multifunction solar cell.

7. The solar cell structure recited in claim 1 wherein the solar cell is a multiband solar cell.

8. The solar cell structure recited in claim 1 wherein the solar cell has a thickness within the range of about 1.0 and 10.0 μm.

9. The solar cell structure recited in claim 1 wherein the substantially transparent solar cell comprises an absorbing layer and an emitter layer.

10. The solar cell structure recited in claim 9 wherein the absorbing layer comprises a dilute nitride absorbing layer having a semiconducting alloy with a group-III element, a group-V element, and nitrogen.

11. The solar cell structure recited in claim 10 wherein the dilute nitride absorbing layer comprises a nitrogen concentration between about 0.1 at. % and 5.0 at. %.

12. The solar cell structure recited in claim 10 wherein the dilute nitride absorbing layer has an electrically active carrier concentration between 10¹⁶ and 5×10¹⁸ cm⁻³.

13. The solar cell structure recited in claim 9 wherein the dilute nitride absorbing layer has an electrically active carrier concentration between 10¹⁶ and 5×10¹⁸ cm⁻³.

14. The solar cell structure recited in claim 1 wherein:
the substantially transparent solar cell comprises GaₓIn_{y}Al_{z}NₐAs_{b}P_{c}Sb_{d}Sₑ;
x<1;
y<1;
z<1;
0.0001<a<0.1;
b<1;
c<1;
d<1; and
e<1.

15. The solar cell structure recited in claim 1 wherein:
the substantially transparent solar cell comprises Ga, As, N, and P; and
the N has a concentration in the range of about 0.01% to about 10%.

16. The solar cell structure recited in claim 15 wherein the substantially transparent solar cell comprises a multiband solar cell.

17. The solar cell structure recited in claim 1 wherein the substantially transparent solar cell absorbs in the ultraviolet electromagnetic spectrum.

18. The solar cell structure recited in claim 1 wherein the substantially transparent solar cell is substantially absorbing at wavelengths less than 400 nm and is substantially transparent at wavelengths greater than 400 nm.

19. The solar cell structure recited in claim 1 wherein the substantially transparent solar cell is substantially absorbing at wavelengths less than 500 nm and is substantially transparent at wavelengths greater than 500 nm.

20. An object comprising the solar cell recited in claim 1.

21. A device comprising the solar cell recited in claim 1 and powered by the energy generated with the solar cell recited in claim 1.

22. The solar cell structure recited in claim 1 further comprising a substantially transparent substrate comprising GaP, sapphire, or SiC.

23. The solar cell structure recited in claim 22 wherein the substantially transparent solar cell comprises Ga, As, N, and P; and
the N has a concentration in the range of about 0.01% to about 10%.
